(19) United States
(12) Patent Application Publication
(10) Pub. No.: US 2006/0071307 A1
(43) Pub. Date: Apr. 6, 2006

(54) Lead frame and semiconductor package therefor

(75) Inventors: Kenichi Shirasaka, Hamamatsu-shi (JP); Hirotaka Eguchi, Isa-gun (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: YAMAHA CORPORATION

(21) Appl. No.: 11/239,030

(22) Filed: Sep. 30, 2005

(30) Foreign Application Priority Data
Oct. 4, 2004 (JP) P2004-291547

(51) Int. Cl. H01L 23/495

(52) U.S. Cl. 257/666

(57) ABSTRACT

A lead frame is produced using a thin metal plate to form a stage for mounting a semiconductor chip, a plurality of leads encompassing the stage, and a frame portion for fixing the stage and leads together. Surfaces of the internal ends of the leads are each expanded in a longitudinal direction and/or a width direction so as to form expanded portions; cutouts are formed in the internal ends of the leads; or the internal ends of the leads are extended outwardly so as to form extended portions. A sealing resin is molded to incorporate the lead frame so as to produce a semiconductor package. Hence, it is possible to increase the overall contact area between the leads and the sealing resin; it is possible to increase the adhesion between the leads and the sealing resin; thus, it is possible to improve the reliability of the semiconductor package in manufacturing.

### BACKGROUND OF THE INVENTION

1. Field of the Invention

The present invention relates to lead frames and semiconductor packages therefor, and in particular to surface-mount-type semiconductor packages (or surface mount chip packages) such as quad flat non-leaded packages (QFN packages) in which terminal ends of leads are exposed on rectangular surfaces of resins for sealing semiconductor devices.

The present application claims priority on Japanese Patent Application No. 2004-291547, the content of which is incorporated herein by reference.

2. Description of the Related Art

Recently, electronic devices have been reduced in dimension, thickness, and weight so that conventionally-known dual inline packages (DIP) have been replaced with surface-mount-type semiconductor packages such as QFN packages in which terminal ends of leads are exposed on rectangular surfaces of resins for sealing semiconductor devices. For example, Japanese Unexamined Patent Applications Publication Nos. 2003-309242 and 2001-257304 disclose examples of QFN packages; and Japanese Unexamined Patent Application Publication No. H06-21315 discloses an example of a lead frame for use in a semiconductor device.

FIG. 36 is a plan view showing an example of a lead frame for use in a conventionally-known QFN package, wherein a lead frame 1 having a rectangular shape includes a stage 3 for mounting a semiconductor chip (or a semiconductor device) 2 thereon, a plurality of leads 4 which are formed so as to encompass the stage 3 and whose internal ends 4a are extended inwardly towards the stage 3, and a plurality of dam bars 5 (constituting a frame portion) which are arranged in peripheral areas of the stage 3 and the leads 4, wherein four connection leads 3a are extended inwardly from four corners and are connected to the stage 3, which is thus fixed in position, and wherein external ends 4b of the leads 4 are directly connected to and fixed to the dam bars 5. A plurality of slits 6 are formed outside of the dam bars 5 respectively.

The lead frame 1 is produced by performing press working or etching on a thin metal plate.

When a QFN package is produced using the lead frame 1, as shown in FIG. 37, the semiconductor chip 2 is bonded onto and fixed to the surface of the stage 3, wherein bonding is performed using bonding wires 7 between pads of the semiconductor chip 2 and the internal ends 4a of the leads 4, which are thus electrically connected together.

Next, a sealing resin 8 composed of epoxy resin is molded to cover the semiconductor chip 2, stage 3, bonding wires 7, and the internal ends 4a of the leads 4, which are thus integrally combined together.

Next, surfaces 4c and back sides 4d of the leads 4, which are exposed and project outside of the sealing resin 8, are subjected to plating so as to form solder plating layers 9, which are used to improve wettability of a solder against the leads 4.

Lastly, prescribed portions of the leads 4, which project outside of the sealing resin 8, are subjected to cutting along a cutting line A, thus making the leads 4 electrically isolated from each other.

Thus, a QFN package (i.e., a surface-mount-type semiconductor package) is produced by way of the aforementioned process.

The conventionally-known QFN package is designed using flat leads; therefore, when a sealing resin is molded incorporating internal ends of leads together with a stage and bonding wires therein, adhesion at contact areas between the leads and the sealing resin may be reduced.

Such a reduction of adhesion may cause separation between the leads and the sealing resin due to thermal stress and external stress or other failures in which wires are electrically broken.

### SUMMARY OF THE INVENTION

It is an object of the invention to provide a semiconductor package and a lead frame, which can improve adhesion at contact areas between leads and a sealing resin, whereby it is possible to prevent leads and the sealing resin from being separated from each other, and it is possible to avoid the occurrence of a failure in which wires are electrically broken. As a result, it is possible to improve the reliability of a semiconductor package using a lead frame.

A lead frame according to the present invention is produced by processing a thin metal plate to form a stage for mounting a semiconductor chip thereon, a plurality of leads that are formed to encompass the stage, and a frame portion for fixing the stage and the leads together. The lead frame can be designed in various ways within the scope of the present invention, examples of which are described below.

In a first aspect, the surfaces of the internal ends of the leads are each expanded in a longitudinal direction and/or a width direction so as to form expanded portions, which are brought into contact with a sealing resin.

In a second aspect, cutouts are formed in the internal ends of the leads so that the surfaces of the internal ends of the leads and the cutouts are brought into contact with a sealing resin.

In a third aspect, the internal ends of the leads are extended outwardly in prescribed sides so as to form extended portions so that the surfaces of the internal ends of the leads and the extended portions are brought into contact with a sealing resin.

All the aforementioned examples increase the overall contact area between the leads and the sealing resin; hence, it is possible to increase the adhesion between the leads and the sealing resin. In addition, it is possible to prevent the circuitry including the leads from being electrically broken due to the separation between the leads and the sealing resin.

The lead frame can be further modified in such a way that the extended portions are formed with respect to the leads that are arranged in proximity to corners of the frame portion; channels and/or recesses are formed in the internal ends of the leads; projections are formed in the internal ends of the leads; through holes running through a thickness direction are formed in the internal ends of the leads; and hollows whose dimensions are larger than bonding areas are formed to cover the bonding areas in the internal ends of the leads. Thus, it is possible to further increase the overall contact area between the leads and the sealing resin; it is possible to further increase the adhesion between the leads and the sealing resin; and it is possible to avoid the occurrence of positional shifts (or positional deviations) between the leads and the sealing resin.

Furthermore, a semiconductor package is produced using the aforementioned lead frame so as to improve the reliability thereof.

### BRIEF DESCRIPTION OF THE DRAWINGS

These and other objects, aspects, and embodiments of the present invention will be described in more detail with reference to the following drawings, in which:

FIG. 1 is a plan view showing a lead frame in accordance with a first embodiment of the present invention;

FIG. 2 is a plan view showing a lead used in the lead frame shown in FIG. 1;

FIG. 3 is a side view of the lead shown in FIG. 2;

FIG. 4 is a cross-sectional view showing essential parts of a QFN package, which is produced using the lead frame shown in FIG. 1;

FIG. 5 is a plan view showing a lead for use in a lead frame in accordance with a second embodiment of the present invention;

FIG. 6 is a side view of the lead shown in FIG. 5;

FIG. 7 is a plan view showing a lead realizing a modification of the lead shown in FIG. 5;

FIG. 8 is a side view of the lead shown in FIG. 7;

FIG. 9 is a plan view showing a lead for use in a lead frame in accordance with a third embodiment of the present invention;

FIG. 10 is a side view of the lead shown in FIG. 9;

FIG. 11 is a plan view showing a lead for use in a lead frame in accordance with a fourth embodiment of the present invention;

FIG. 12 is a side view of the lead shown in FIG. 11;

FIG. 13 is a plan view showing a lead realizing a modification of the lead shown in FIG. 11;

FIG. 14 is a side view of the lead shown in FIG. 13;

FIG. 15 is a plan view showing a lead for use in a lead frame in accordance with a fifth embodiment of the present invention;

FIG. 16 is a side view of the lead shown in FIG. 15;

FIG. 17 is a plan view showing a lead realizing a modification of the lead shown in FIG. 15;

FIG. 18 is a side view of the lead shown in FIG. 17;

FIG. 19 is a plan view showing a lead for use in a lead frame in accordance with a sixth embodiment of the present invention;

FIG. 20 is a side view of the lead shown in FIG. 19;

FIG. 21 is a plan view showing essential parts of a lead frame in accordance with a seventh embodiment of the present invention;

FIG. 22 is a side view showing a lead of the lead frame shown in FIG. 21;

FIG. 23 is a plan view showing essential parts of a lead frame in accordance with an eighth embodiment of the present invention;

FIG. 24 is a side view showing a lead of the lead frame shown in FIG. 23;

FIG. 25 is a plan view showing a lead realizing a modification of the lead shown in FIG. 24;

FIG. 26 is a front view of the lead shown in FIG. 25;

FIG. 27 is a plan view showing a lead frame in accordance with a ninth embodiment of the present invention;

FIG. 28 is plan view showing a lead of the lead frame shown in FIG. 27;

FIG. 29 is a front view of the lead shown in FIG. 28;

FIG. 30 is a plan view showing another lead of the lead frame shown in FIG. 27;

FIG. 31 is a front view of the lead shown in FIG. 30;

FIG. 32 is a plan view showing a lead realizing a modification of the lead shown in FIG. 28;

FIG. 33 is a plan view showing a lead for use in a lead frame in accordance with a tenth embodiment of the present invention;

FIG. 34 is a side view of the lead shown in FIG. 33;

FIG. 35 is a cross-sectional view showing the lead of FIG. 33 that is encapsulated in a sealing resin;

FIG. 36 is a plan view showing a lead frame for use in a conventionally-known QFN package; and

FIG. 37 is a cross-sectional view showing essential parts of the QFN package using the lead frame shown in FIG. 36.

### DESCRIPTION OF THE PREFERRED EMBODIMENTS

The present invention will be described in further detail by way of examples with reference to the accompanying drawings.

### 1. First Embodiment

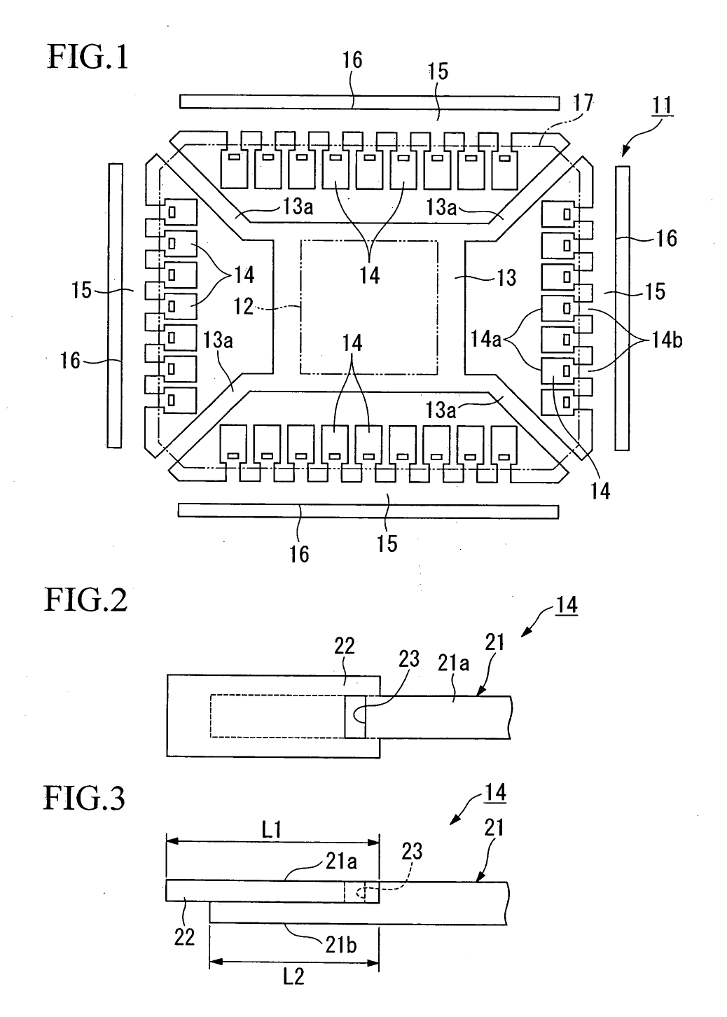

FIG. 1 is a plan view showing a lead frame in accordance with a first embodiment of the present invention, wherein this lead frame is used for a QFN package which is an example of a surface-mount-type semiconductor package.

In FIG. 1, reference numeral 11 designates a lead frame, which is produced by performing press working or etching on a thin metal plate that is composed of phosphor bronze, copper, iron-nickel alloy, and the like.

The lead frame 11 includes a stage 13 having a rectangular shape in a plan view, on which a semiconductor chip (or a semiconductor device constituting a main component of the QFN package) 12 is mounted, a plurality of leads 14 (having comb-like or strip-like shapes) which are arranged to encompass the stage 13 and whose internal ends 14a are extended inwardly towards the stage 13, and a plurality of dam bars 15 (constituting a frame portion) which are arranged in peripheral areas of the stage 13 and the leads 14, wherein four corners are connected to and fixed to the stage 13 via connection leads 13a, and wherein external ends 14b of the leads 14 are directly connected to and fixed to the dam bars 15. Slits 16 are formed outside of and in parallel with the dam bars 15.

FIGS. 2 and 3 show the shape of the lead 14 in which a surface 21a of an internal end portion 21 is elongated in a longitudinal direction (i.e., left and right directions) and is also expanded in a width direction (i.e., upper and lower directions), thus forming an expanded portion 22.

The expanded portion 22 has a prescribed length L1, which is increased to be longer than a length L2 of a back side 21b opposite to the surface 21a in a longitudinal direction. A recess 23 is formed on the surface 21a of the expanded portion 22 at a prescribed position, which is close to the dam bar 15 (not shown).

The recess 23 corresponds to a rectangular opening in which the width thereof matches the width of the lead 14, and the length thereof is shorter than the width thereof, wherein the depth thereof is set to a range from ⅓ to ⅔ of the thickness of the lead 14.

When a sealing resin is molded, it is partially introduced into the recess 23 so as to increase the overall contact area between the lead 14 and the sealing resin, whereby it is possible to increase the adhesion strength between the lead 14 and the sealing resin.

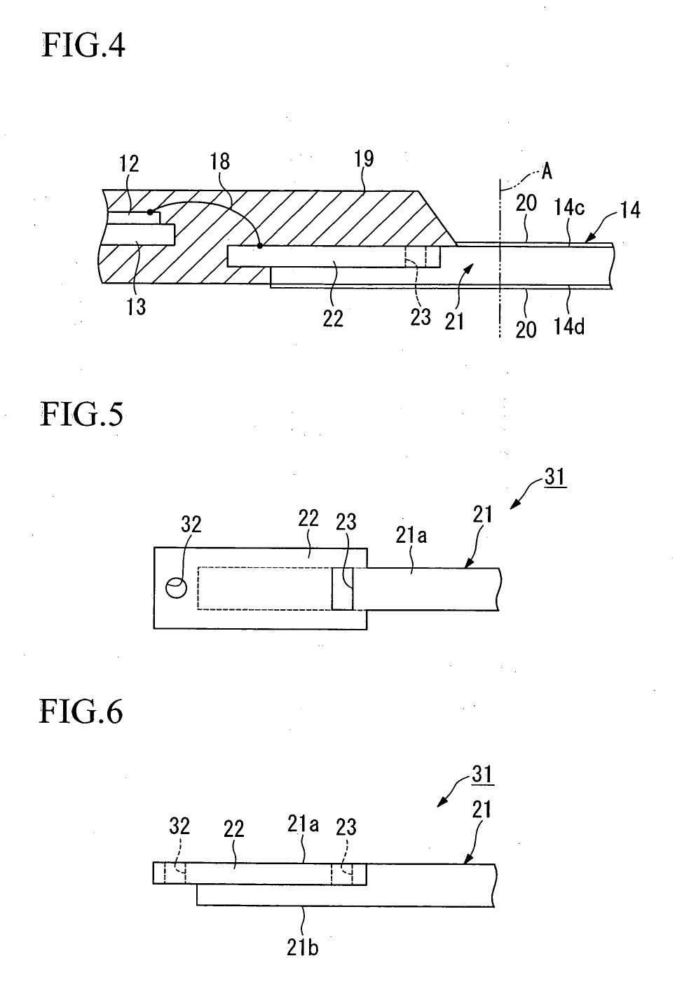

When a QFN package is to be produced using the lead frame 11, as shown in FIG. 4, a semiconductor chip 12 is bonded and fixed onto the surface of the stage 13; then, the expanded portions 22 of the leads 14 are subjected to bonding using bonding wires 18 and are thus electrically connected to pads of the semiconductor chip 12.

Next, a sealing resin 19 composed of epoxy resin is molded so as to incorporate the semiconductor chip 12, stage 13, bonding wires 18, and the internal end portions 21 of the leads 14 including the expanded portions 22, all of which are thus integrally combined.

In the molding step, a melted resin is introduced into the recesses 23, which are thus filled with the resin. Then, curing (i.e., thermal treatment) is effected so as to harden the sealing resin 19.

Due to the provision of the recesses 23 formed in the expanded portions 22 of the leads 14, it is possible to increase the overall contact areas between the leads 14 and the sealing resin 19; thus, it is possible to increase the adhesion strength between the leads 14 and the sealing resin 19.

After the completion of the hardening of the sealing resin 19, a very high adhesion strength is established between the leads 14 and the sealing resin 19.

In addition, the sealing resin 19 is partially introduced into the recesses 23 of the leads 14 and is then hardened; that is, the hardened resin is partially engaged with the recesses; thus, it is possible further increase the adhesion between the leads 14 and the sealing resin 19.

Next, surfaces 14c and back sides 14d of external ends of the leads 14, which are exposed outside of the sealing resin 19, are subjected to plating so as to form plated layers 20 for use in soldering.

Lastly, the external ends of the leads 14, which are exposed outside of the sealing resin 19, are subjected to cutting along a cutting line A, so that the leads 14 are electrically isolated from each other.

As described above, it is possible to produce a QFN package which is an example of a surface-mount-type semiconductor package.

In the lead frame 11 of the present embodiment, the surface 21a of the internal end portion 21 of the lead 14 is expanded in both the longitudinal direction and width direction so as to form the expanded portion 22 in which the recess 23 is formed on the surface at a prescribed position close to the dam bar 15; hence, it is possible to improve the adhesion between the lead 14 and the sealing resin 19.

In the QFN package using the lead frame 11 of the present embodiment, it is possible to reliably avoid the occurrence of a separation between the leads 14 and the sealing resin 19; hence, it is possible to avoid the occurrence of a failure, that is, it is possible to prevent the circuitry including the leads 14 from being electrically broken. Thus, it is possible to improve the reliability with respect to the QFN package.

### 2. Second Embodiment

FIG. 5 is a plan view showing a lead adapted to a lead frame in accordance with a second embodiment of the present invention; and FIG. 6 is a side view of the lead shown in FIG. 5. That is, the second embodiment differs from the first embodiment in such a way that compared with the lead 14 used in the first embodiment, a lead 31 used in the second embodiment has a through hole 32 running through an expanded portion 22 in its thickness direction, wherein the through hole 32 is formed at a prescribed position of the expanded portion 22 in proximity to its end portion lying in the longitudinal direction.

Due to the provision of the through hole 32 running through in the thickness direction in proximity to the end portion of the expanded portion 22 lying in the longitudinal direction, when a sealing resin is molded, it is partially introduced into both of the through hole 32 and the recess 23 of the lead 31 and is then hardened; hence, it is possible to further increase the overall contact area between the lead 31 and the sealing resin; additionally, it is possible to prevent the lead 31 and the sealing resin from being mutually shifted in position. Thus, it is possible to further improve the adhesion between the lead 31 and the sealing resin, wherein it is unlikely that any positional shift will occur between the lead 31 and the sealing resin.

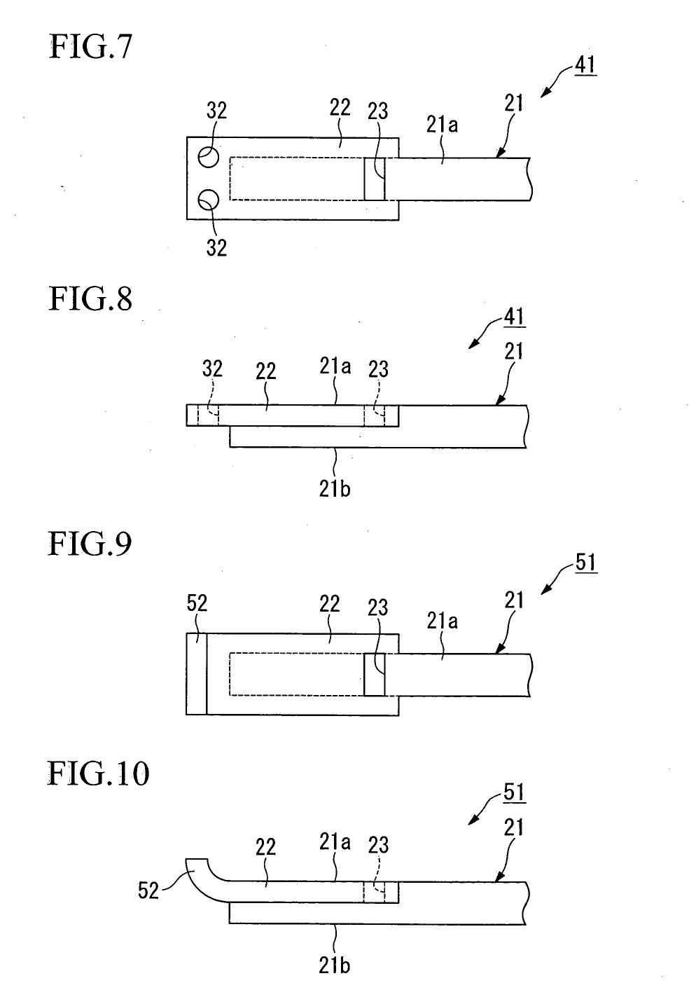

FIG. 7 is a plan view showing a lead 41 realizing a modification of the lead 31; and FIG. 8 is a side view of the lead 41.

The lead 41 has two through holes 32 running through in the thickness direction in the end portion of the expanded portion 22 lying in the longitudinal direction; hence, it is possible to further improve the adhesion between the sealing resin and the lead 41 compared with the lead 31, wherein it is unlikely that a positional shift occurs between the lead 41 and the sealing resin.

According to the present embodiment that is characterized by using the aforementioned leads 31 and 41, at least one through hole 32 running through in the thickness direction is formed in the end portion of the expanded portion 22 lying in the longitudinal direction; hence, it is possible to further improve the adhesion between the leads 31 and 41 and the sealing resin.

When a QFN package is produced using the lead frame having the lead 31 or 41, it is possible to avoid the occurrence of a failure, that is, it is possible to prevent the circuitry including the lead 31 or 41 from being electrically broken due to the separation between the lead 31 or 41 and the sealing resin. Thus, it is possible to improve the reliability with respect to the QFN package.

### 3. Third Embodiment

FIG. 9 is a plan view showing a lead 51 for use in a lead frame in accordance with a third embodiment of the present invention; and FIG. 10 is a side view of the lead 51. The third embodiment differs from the first embodiment in such a way that compared with the lead 14 used in the first embodiment, the lead 51 used in the third embodiment has an expanded portion 22 whose end portion is bent upwardly so as to form a bent portion 52, which increases the overall contact area between the lead 51 and the sealing resin so that the adhesion therebetween is improved.

The lead 51 of the third embodiment can demonstrate prescribed effects similar to those of the lead 14 of the first embodiment.

In the third embodiment, the end portion of the expanded portion 22 of the lead 51 is bent upwardly so as to form the bent portion 52, by which it is possible to further improve the adhesion between the lead 51 and the sealing resin.

### 4. Fourth Embodiment

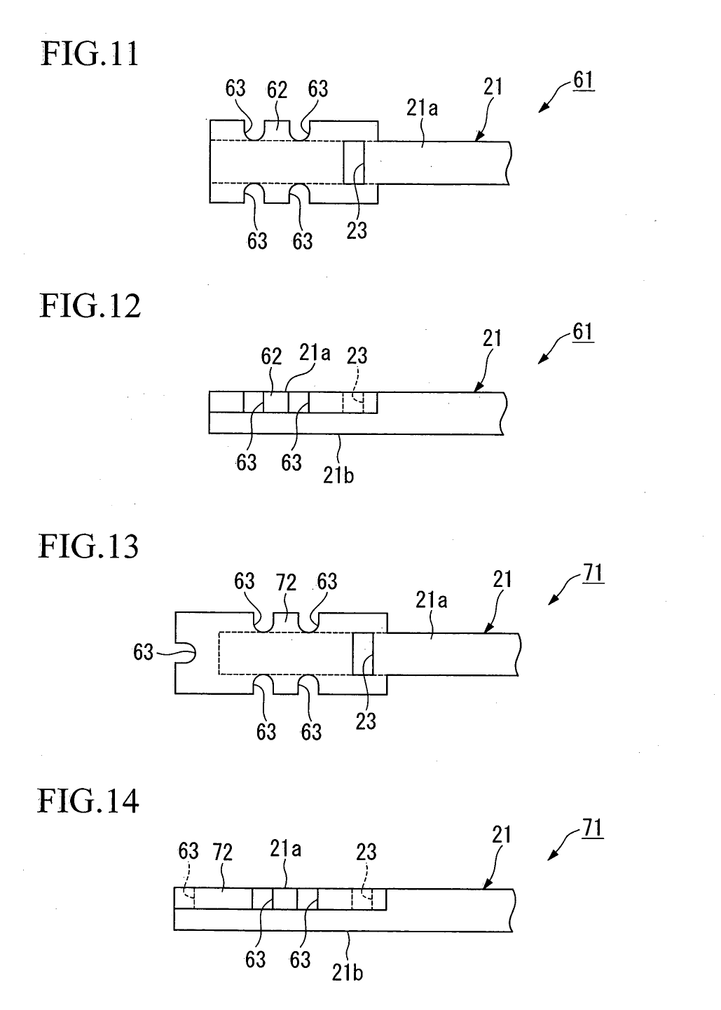

FIG. 11 is a plan view showing a lead 61 for use in a lead frame in accordance with a fourth embodiment of the present invention; and FIG. 12 is a side view of the lead 61. The fourth embodiment differs from the first embodiment such that compared with the lead 14 used in the first embodiment, the lead 61 used in the fourth embodiment has a surface 21a of an internal end portion 21, which is expanded only in a width direction (i.e., upper and lower directions in FIG. 11; and a perpendicular direction of the sheet of FIG. 12) so as to form an expanded portion 62, wherein cutouts 63 are formed on both sides of the expanded portion 62 lying in the width direction.

Due to the provision of the lead 61 in which the cutouts 63 are formed on both sides of the expanded portion 62 expanded only in the width direction, when a sealing resin is molded, it is partially introduced into both of the cutouts 63 and the recess 23 of the lead 61 and is then hardened; hence, it is possible to further increase the overall contact area between the lead 61 and the sealing resin, whereby it is possible to avoid the occurrence of a positional shift between the lead 61 and the sealing resin. Thus, it is possible to further improve the adhesion between the lead 61 and the sealing resin.

FIG. 13 is a plan view showing a lead 71 realizing a modification of the lead 61; and FIG. 14 is a side view of the lead 71. In the lead 71, the surface 21a of the internal end 21 is expanded in both the longitudinal direction (i.e., left and right directions) and width direction (i.e., upper and lower directions in FIG. 13; and the perpendicular direction of the sheet of FIG. 14) so as to form an expanded portion 72, wherein an additional cutout 63 is formed at the end portion of the expanded portion 72 lying in the longitudinal direction.

Due to the provision of the lead 71 in which the expanded portion 72 is expanded in both the longitudinal direction and width direction and in which the additional cutout 63 is formed at the end portion of the expanded portion 72, it is possible to further improve the adhesion between the sealing resin and the lead 71 compared with the lead 61.

In the present embodiment using the leads 61 and 71, it is possible to demonstrate prescribed effects similar to those of the first embodiment using the lead 14.

In addition, the present embodiment is characterized in that the surface 21a of the internal end portion 21 is expanded only in the width direction so as to form the expanded portion 62 or is expanded in both the longitudinal direction and width direction so as to form the expanded portion 72, wherein the cutouts 63 are appropriately formed at prescribed positions with respect to the expanded portions 62 and 72. Thus, it is possible to further improve the adhesion between the sealing resin and the leads 61 and 71.

### 5. Fifth Embodiment

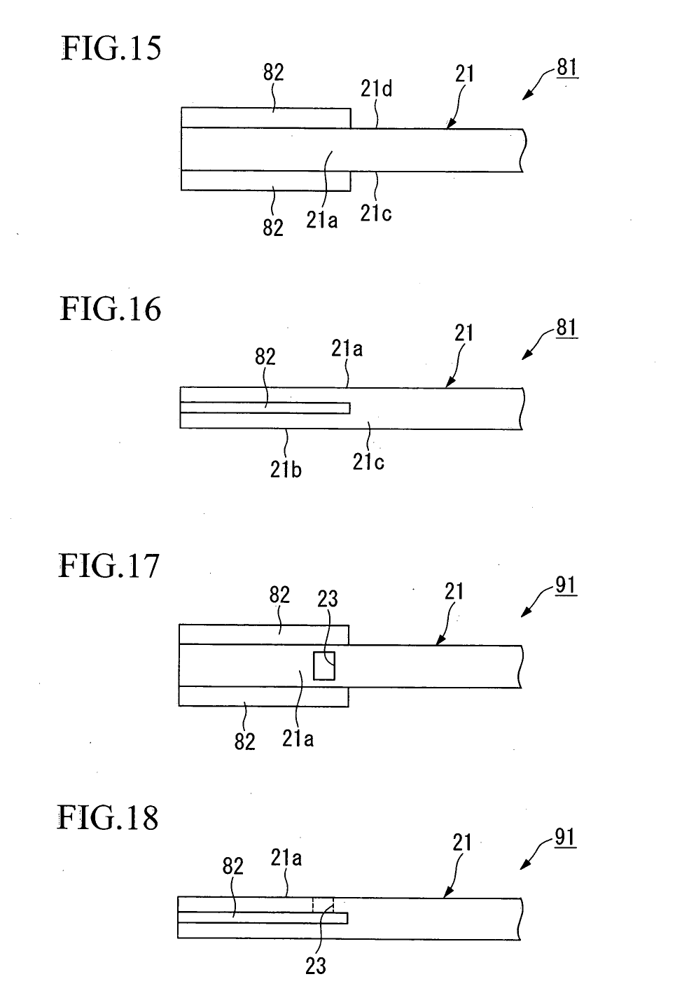

FIG. 15 is a plan view showing a lead 81 for use in a lead frame in accordance with a fifth embodiment of the present invention; and FIG. 16 is a side view of the lead 81. The fifth embodiment differs from the first embodiment such that compared with the lead 14 used in the first embodiment, the lead 81 used in the fifth embodiment has flanges 82, each having a plate-like shape, which project vertically and outwardly from sides 21c and 21d of the internal end portion 21, wherein the surface 21a of the internal end portion 21 as well as the flanges 82 are collectively brought into contact with a sealing resin.

Due to the provision of the flanges 82 formed on the sides 21c and 21d of the internal end 21 portion of the lead 81, when a sealing resin is molded, all the upper surfaces of the flanges 82 and the surface 21a of the internal end portion 21 are brought into contact with the sealing resin; hence, it is possible to remarkably increase the overall contact area between the lead 81 and the sealing resin, wherein it is possible to avoid the occurrence of a positional shift between the lead 81 and the sealing resin. Thus, it is possible to further improve the adhesion between the lead 81 and the sealing resin.

FIG. 17 is a plan view showing a lead 91 realizing a modification of the lead 81; and FIG. 18 is a side view of the lead 91. Compared with the lead 81, the lead 91 has a recess 23 that is formed on the surface 21a of the internal end portion 21 at a prescribed position close to the dam bar (not shown).

Due to the formation of the recess 23 on the surface 21a of the internal end 21 at the prescribed position close to the dam bar, when a sealing resin is molded, the overall contact area is improved between the sealing resin and the lead 91 having the recess 23 in addition to the flanges 82; hence, it is possible to further improve the adhesion between the lead 91 and the sealing resin.

In the present embodiment using the leads 81 and 91, it is possible to demonstrate prescribed effects similar to those of the first embodiment using the lead 14.

Due to the provision of the flanges 82 projecting from the sides 21c and 21d of the internal end portion 21, it is possible to further improve the adhesion between the sealing resin and the leads 81 and 91.

### 6. Sixth Embodiment

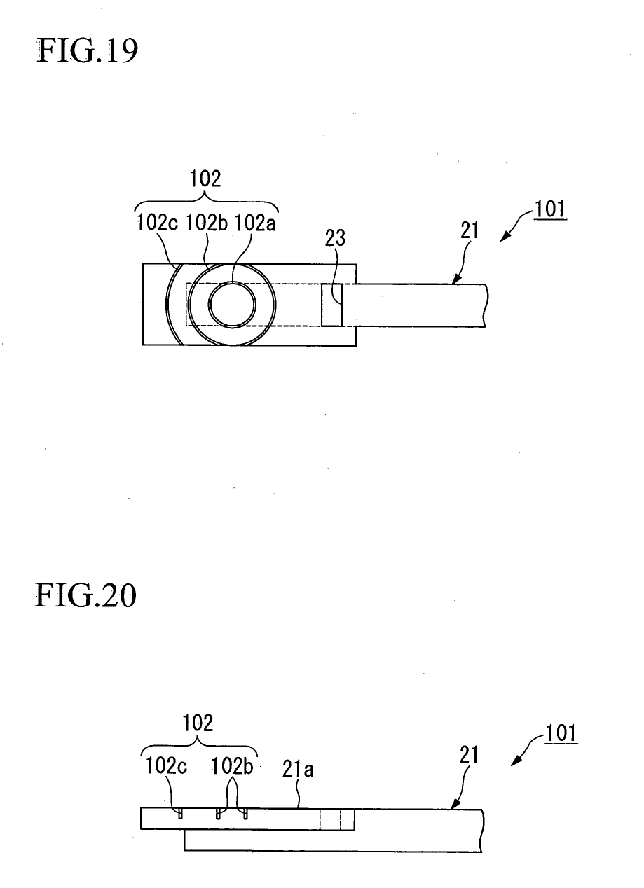

FIG. 19 is a plan view showing a lead 101 for use in a lead frame in accordance with a sixth embodiment of the present invention; and FIG. 20 is a side view of the lead 101. The sixth embodiment differs from the first embodiment such that compared with the lead 14 used in the first embodiment, the lead 101 used in the sixth embodiment has concentric channels 102 formed on the surface of the expanded portion 22. Specifically, the concentric channels 102 include a circular channel 102a, a pair of ark-like channels 102b, and an ark-like channel 102c.

Due to the formation of the concentric channels 102 on the surface of the expanded portion 22, when a sealing resin is molded, all the concentric channels 102 and the expanded portion 22 are brought into contact with the sealing resin; hence, it is possible to increase the overall contact area between the lead 101 and the sealing resin, wherein it is possible to further improve the adhesion between the lead 101 and the sealing resin.

In the present embodiment using the lead 101, it is possible to demonstrate prescribed effects similar to those of the first embodiment using the lead 14.

Due to the formation of the concentric channels 102 on the surface of the expanded portion 22, it is possible to further improve the adhesion between the lead 101 and the sealing resin.

### 7. Seventh Embodiment

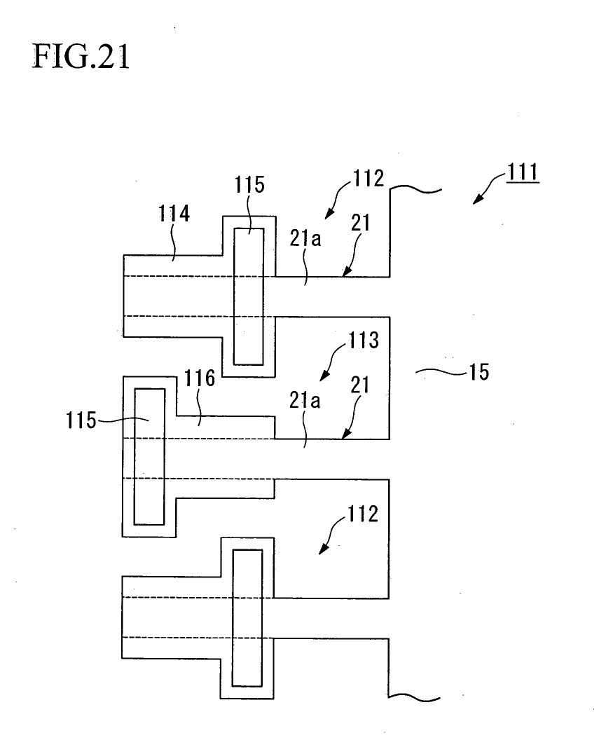

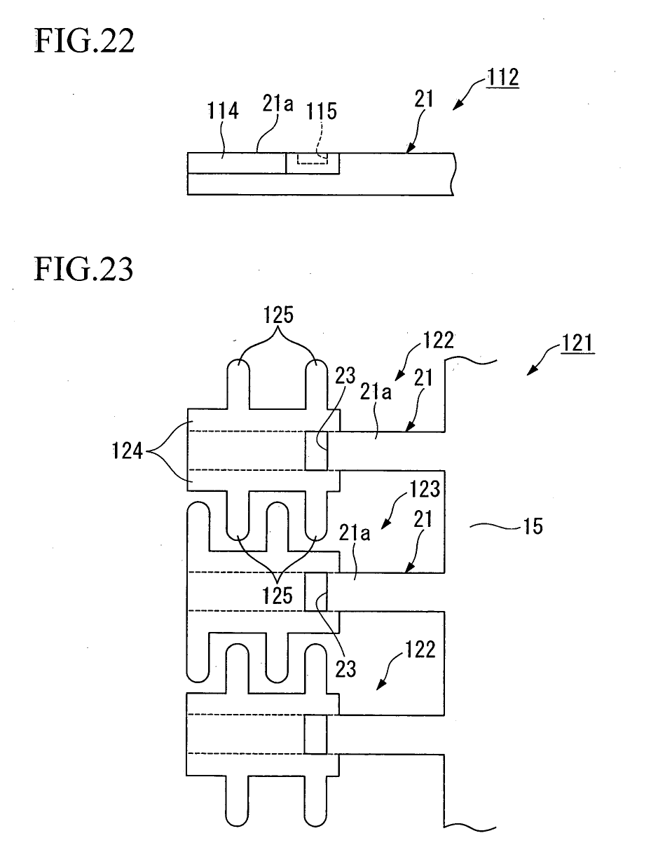

FIG. 21 is a plan view showing essential parts of a lead frame in accordance with a seventh embodiment of the present invention; and FIG. 22 is a side view showing a lead of the lead frame shown in FIG. 21. The seventh embodiment provides an example of the lead frame adapted to a surface-mount-type semiconductor package of a QFN type.

Specifically, a lead frame 111 has two types of leads 112 and 113, which are alternately arranged to encompass a stage (not shown) and which are respectively connected and fixed to dam bars 15.

In the lead 112, the surface 21a of the internal end portion 21 is expanded in a step-like manner in a width direction (i.e., upper and lower directions in FIG. 21; the perpendicular direction of the sheet of FIG. 22) towards the dam bar 15 so as to form an expanded portion 114. The expanded portion 114 has a further expanded terminal area having a rectangular shape lying in proximity to the dam bar 115, wherein a rectangular recess 115 whose opening area is smaller than the further expanded terminal area is formed in the further expanded terminal area.

The side portions of the lead 113 are shaped so as to be substantially complementary to the leads 112 adjoining thereto, wherein the surface 21a of the internal end portion 21 is expanded in a step-like manner in a width direction (i.e., upper and lower directions in FIG. 21) towards the stage (not shown) so as to form an expanded portion 116, which has a further expanded terminal area having a rectangular shape lying in proximity to the stage, wherein a rectangular recess 115 is formed in the further expanded terminal area.

As described above, the leads 112 and 113 have the expanded portions 114 and 116 in which the rectangular recesses 115 are formed in the further expanded terminal areas. That is, due to the formation of the expanded portions 114 and 116 having the rectangular recesses 115, it is possible to increase the overall contact areas between the leads 112 and 113 and a sealing resin (not shown); hence, it is possible to increase the adhesion strength between the leads 112 and 113 and the sealing resin.

The sealing resin is partially introduced into the rectangular recesses 115 of the leads 112 and 113 and is then hardened; hence, it is possible to further increase the adhesion between the leads 112 and 113 and the sealing resin.

In the present embodiment having the leads 112 and 113, it is possible to demonstrate prescribed effects similar to those of the first embodiment using the lead 14.

As the rectangular recesses 115 are formed in the further expanded terminal areas of the expanded portions 114 and 116, it is possible to further improve the adhesion between the leads 112 and 113 and the sealing resin.

### 8. Eighth Embodiment

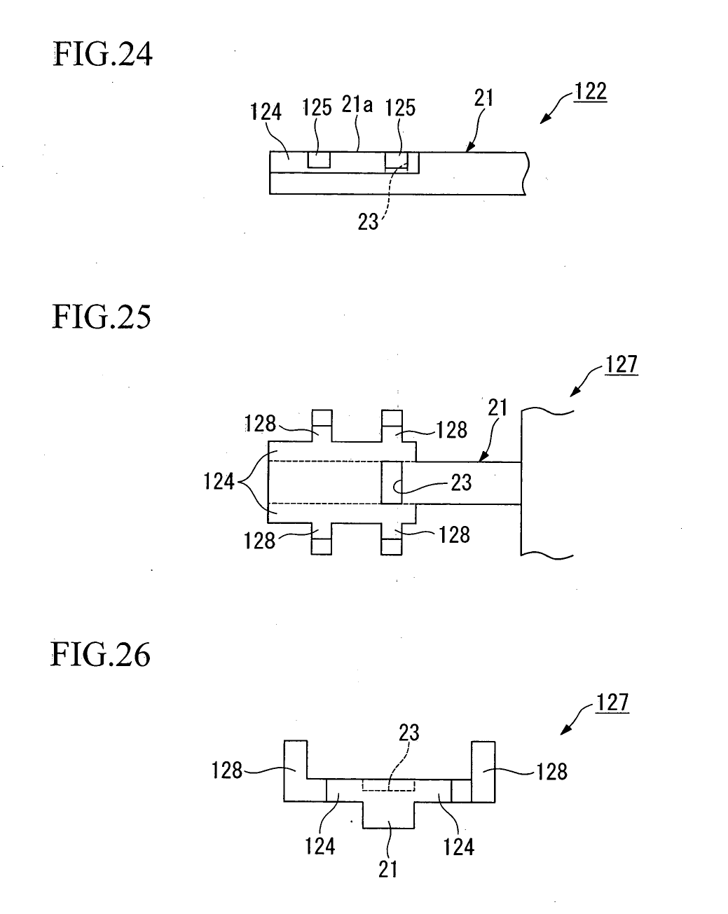

FIG. 23 is a plan view showing essential parts of a lead frame in accordance with an eighth embodiment of the present invention; and FIG. 24 is a side view showing a lead of the lead frame shown in FIG. 23. That is, a lead frame 121 shown in FIG. 23 has two types of leads 122 and 123, which are arranged alternately to encompass a stage (not shown) and which are respectively connected and fixed to dam bars 15.

In the lead 122, the surface 21a of the internal end portion 21 is expanded in a width direction (i.e., upper and lower directions in FIG. 23) so as to form expanded portions 124, wherein the recess 23 is formed on the surface of the expanded portion in proximity to the dam bar 15, and wherein projections 125 each having a prism shape project perpendicularly from the side ends of the expanded portions 124.

Both sides of the lead 123 are shaped to be complementary to the leads 122 adjoining thereto, wherein they are expanded in the width direction to form the expanded portions 124, and wherein the projections 125 each having a prism shape project perpendicularly from the side ends of the expanded portions 124.

The projections 125 of the lead 122 and the projections 125 of the lead 123 are alternately arranged in such a way that they do not overlap with each other in the longitudinal direction.

Due to the provision of the projections 125 that project from the leads 122 and 123 respectively and that are arranged alternately so as not to overlap with each other in the longitudinal direction, it is possible to increase the overall contact area between the leads 122 and 123 and a sealing resin; hence, it is possible to increase the adhesion strength between the leads 122 and 123 and the sealing resin.

FIG. 25 is a plan view showing a lead 127 realizing a modification of the lead 122; and FIG. 26 is a front view of the lead 127. The lead 127 provides L-shaped projections 128, which are made by bending each of prism-shaped projections in an L-shape, instead of the aforementioned projections 125 that project perpendicularly from the side ends of the expanded portions 124.

Due to the provision of the L-shaped projections 128, when a sealing resin is molded, it is possible to remarkably increase the overall contact area between the lead 127 and the sealing resin because of the collaboration of the L-shaped projections 128 and the recess 23; hence, it is possible to remarkably improve the adhesion between the lead 127 and the sealing resin.

In the present embodiment having the leads 122 and 123, it is possible to demonstrate prescribed effects similar to those of the first embodiment using the lead 14.

Due to the provision of the projections 125 that project from the leads 122 and, 123 respectively, it is possible to further improve the adhesion between the leads 122 and 123 and the sealing resin.

By using the L-shaped projections 128 instead of the projections 125, it is possible to remarkably improve the adhesion between the lead 127 and the sealing resin.

### 9. Ninth Embodiment

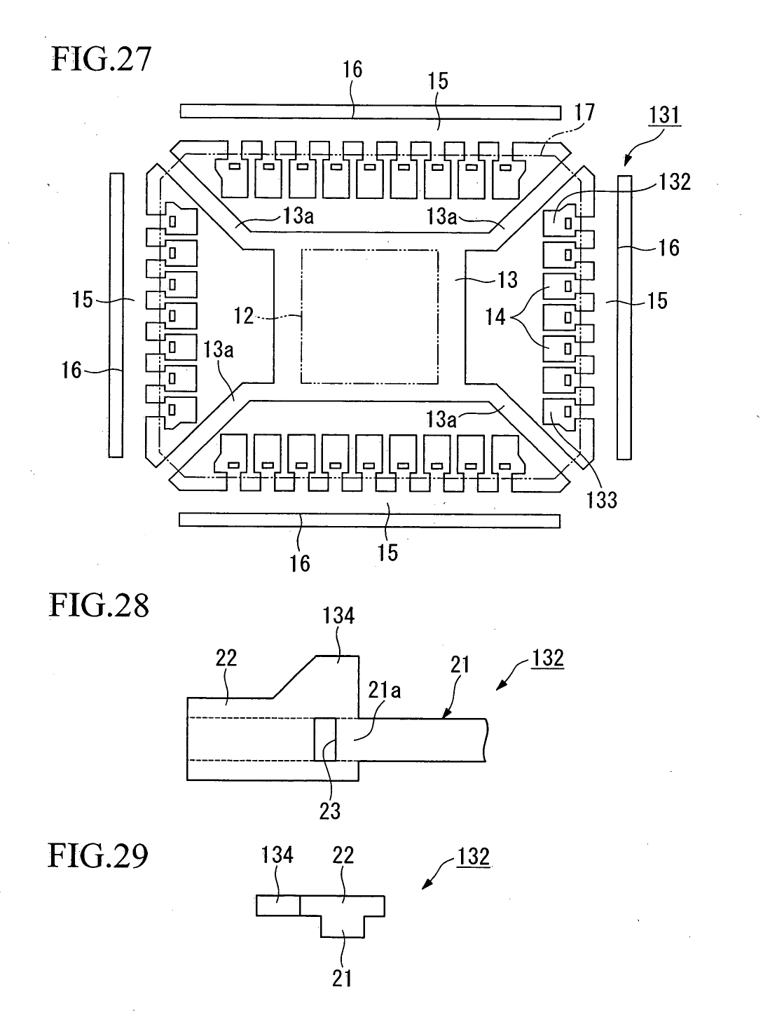

FIG. 27 is a plan view showing a lead frame 131 in accordance with a ninth embodiment of the present invention. Compared with the lead frame 11 of the first embodiment, the lead frame 131 of the ninth embodiment is designed such that outermost leads 132 and 133 have different shapes compared with other leads 14 disposed along a dam bar 15.

Specifically, the outermost lead 132 has an expanded portion 22 as shown in FIGS. 28 and 29, wherein a corner of the expanded portion 22 is further extended in a triangular manner towards a connection lead 13a so as to form an extended portion 134.

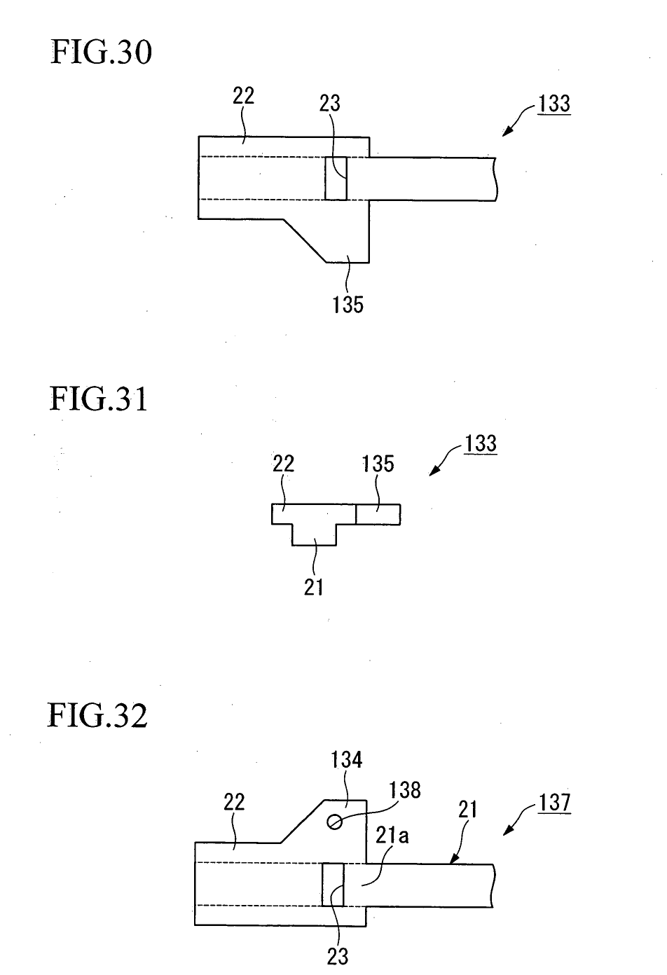

Similarly, the outermost lead 133 has an expanded portion 22 as shown in FIGS. 30 and 31, wherein an opposite corner of the expanded portion 22 is further extended in a triangular manner towards a connection lead 13a so as to form an extended portion 135.

Due to the provision of the extended portions 134 and 135 that are extended towards the connection leads 13a from the expanded portions 22 of the leads 132 and 133 respectively, it is possible to increase the overall contact area between the leads 132 and 133 and a sealing resin; hence, it is possible to increase the adhesion strength between the leads 132 and 133 and the sealing resin.

FIG. 32 is a plan view showing a lead 137 realizing a modification of the lead 132, wherein the lead 137 has a through hole 138 running through the extended portion 134 in its thickness direction.

Due to the formation of the through hole 138 in the extended portion 134, when a sealing resin is molded, it is possible to remarkably increase the overall contact area between the lead 137 and the sealing resin because of the collaboration of the extended portion 134, through hole 138, and recess 23; hence, it is possible to remarkably increase the adhesion between the lead 137 and the sealing resin.

In the present embodiment having the leads 132 and 133, it is possible to demonstrate prescribed effects similar to those of the first embodiment using the lead 14.

Due to the provision of the extended portions 134 and 135 in the leads 132 and 133, it is possible to remarkably increase the adhesion between the leads 132 and 133 and the sealing resin.

Due to the formation of the through hole 138 in the extended portion 134, it is possible to further improve the adhesion between the leads 137 and the sealing resin.

Incidentally, it is possible to further form a through hole 138 running through the extended portion 135 of the lead 133, whereby the lead 133 can demonstrate effects similar to those of the lead 137.

### 10. Tenth Embodiment

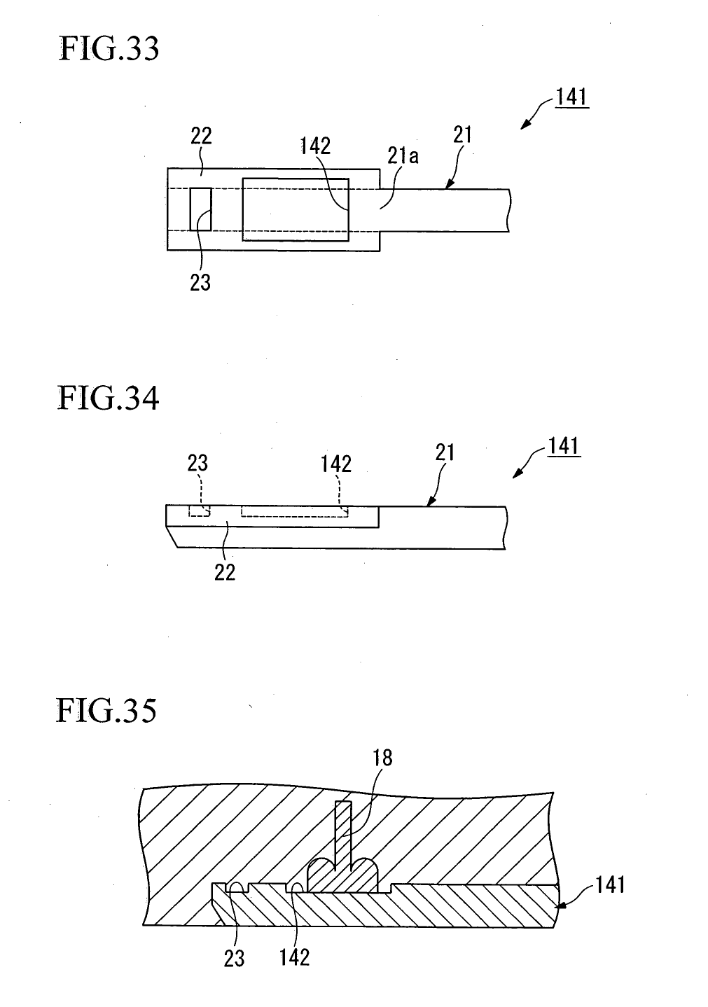

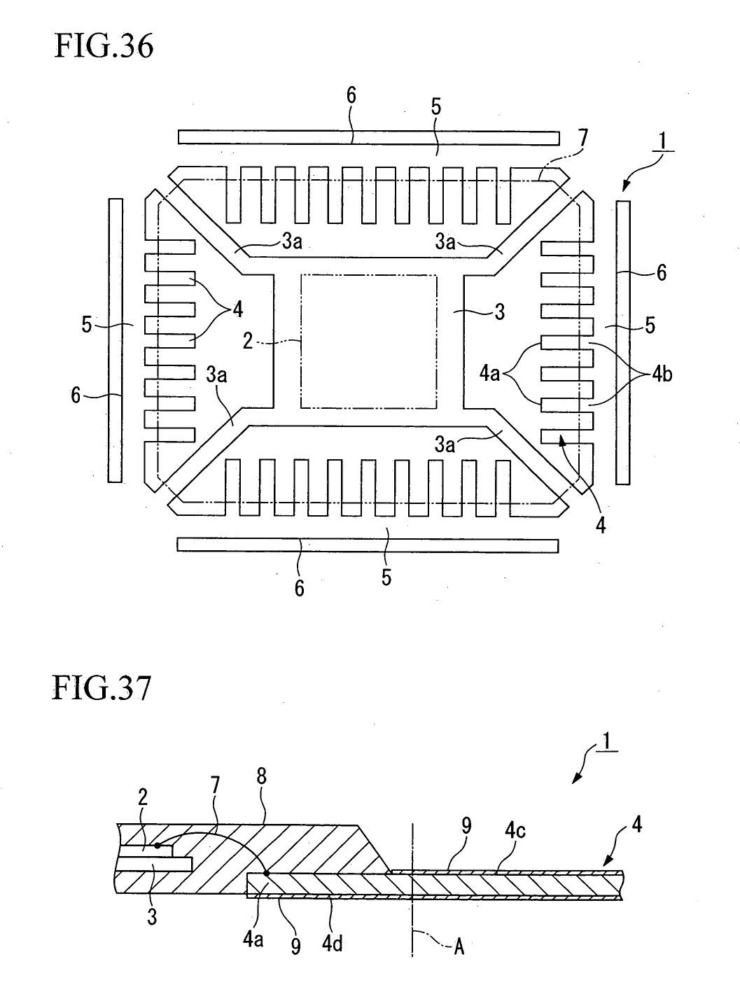

FIG. 33 is a plan view showing a lead 141 for use in a lead frame in accordance with a tenth embodiment of the present invention; and FIG. 34 is a side view of the lead 141. The lead 141 of the tenth embodiment differs from the lead 14 of the first embodiment such that a hollow 142 whose dimensions are larger than those of a bonding area is formed to cover the bonding area on the surface of the expanded portions 22.

As shown in FIG. 35, bonding is performed using a bonding wire 18 so as to establish an electric connection between a pad of a semiconductor chip (not shown) and the hollow 142; then, a sealing resin composed of epoxy resin is molded to encapsulate the bonding wire 18 and the internal end of the lead 141, which are thus integrally combined.

In a molding step, the sealing resin is partially introduced into the recess 23 and the hollow 142 and is then hardened. This enhances an engagement between the lead 141 and the sealing resin. Thus, it is possible to remarkably increase the overall contact area between the lead 141 and the sealing resin; hence, it is possible to further increase the adhesion between the lead 141 and the sealing resin.

In the present embodiment having the lead 141, it is possible to demonstrate prescribed effects similar to those of the first embodiment using the lead 14.

Due to the provision of the hollow 142 whose dimensions are larger than those of the bonding area and which is formed so as to cover the bonding area on the surface of the expanded portions 22, it is possible to enhance an engagement between the lead 14 and the sealing resin. This also remarkably increases the overall contact area between the lead 141 and the sealing resin; hence, it is possible to further improve the adhesion between the lead 141 and the sealing resin.

As described heretofore, the present invention is basically designed such that the surface of the internal end of the lead is expanded in the longitudinal direction and/or the width direction so as to improve the adhesion between the lead and the sealing resin. That is, the present invention is applicable to various types of surface-mount-type semiconductor packages including QFN packages; hence, it demonstrates a great industrial effect

Finally, the present invention is not necessarily limited to the aforementioned embodiments, which are illustrative and not restrictive; hence, any changes and modifications that fall within the scope of the invention are therefore intended to be embraced by the claims.

1. A lead frame comprising:
a stage for mounting a semiconductor chip thereon;
a plurality of leads that are formed to encompass the stage; and
a frame portion for fixing the stage and the plurality of leads together,
wherein surfaces of internal ends of the leads are each expanded in a longitudinal direction and/or a width direction so as to form expanded portions, which are brought into contact with a sealing resin.

2. A lead frame comprising:
a stage for mounting a semiconductor chip thereon;
a plurality of leads that are formed to encompass the stage; and
a frame portion for fixing the stage and the plurality of leads together,
wherein cutouts are formed in internal ends of the leads so that surfaces of the internal ends of the leads and the cutouts are brought into contact with a sealing resin.

3. A lead frame comprising:
a stage for mounting a semiconductor chip thereon;
a plurality of leads that are formed to encompass the stage; and
a frame portion for fixing the stage and the plurality of leads together,
wherein internal ends of the leads are extended outwardly in prescribed sides so as to form extended portions so that surfaces of the internal ends of the leads and the extended portions are brought into contact with a sealing resin.

4. A lead frame according to claim 3, wherein the extended portions are formed with respect to the leads that are arranged in proximity to corners of the frame portion.

5. A lead frame according to claim 1, wherein channels and/or recesses are formed in the internal ends of the leads.

6. A lead frame according to claim 1, wherein projections are formed in the internal ends of the leads.

7. A lead frame according to claim 1, wherein through holes running through a thickness direction are formed in the internal ends of the leads.

8. A lead frame according to claim 1, wherein hollows whose dimensions are larger than bonding areas are formed to cover the bonding areas in the internal ends of the leads.

9. A lead frame according to claim 1, wherein hollows whose dimensions are larger than bonding areas are formed to cover the bonding areas in the internal ends of the leads, and wherein the internal ends of the leads including the bonding areas are expanded in prescribed directions.

10. A semiconductor package in which a sealing resin is molded to incorporate a lead frame that comprises a stage for mounting a semiconductor chip thereon, a plurality of leads that are formed to encompass the stage, and a frame portion for fixing the stage and the plurality of leads together, wherein surfaces of internal ends of the leads are each expanded in a longitudinal direction and/or a width direction so as to form expanded portions, which are brought into contact with the sealing resin.

11. A semiconductor package in which a sealing resin is molded to incorporate a lead frame that comprises a stage for mounting a semiconductor chip thereon, a plurality of leads that are formed to encompass the stage, and a frame portion for fixing the stage and the plurality of leads together, wherein cutouts are formed in internal ends of the leads so that surfaces of the internal ends of the leads and the cutouts are brought into contact with the sealing resin.

12. A semiconductor package in which a sealing resin is molded to incorporate a lead frame that comprises a stage for mounting a semiconductor chip thereon, a plurality of leads that are formed to encompass the stage; and a frame portion for fixing the stage and the plurality of leads together, wherein internal ends of the leads are extended outwardly in prescribed sides so as to form extended portions so that surfaces of the internal ends of the leads and the extended portions are brought into contact with the sealing resin.

13. A semiconductor package according to claim 12, wherein the extended portions are formed with respect to the leads that are arranged in proximity to corners of the frame portion.

14. A semiconductor package according to claim 10, wherein channels and/or recesses are formed in the internal ends of the leads.

15. A semiconductor package according to claim 10, wherein projections are formed in the internal ends of the leads.

16. A semiconductor package according to claim 10, wherein through holes running through a thickness direction are formed in the internal ends of the leads.

17. A semiconductor package according to claim 10, wherein hollows whose dimensions are larger than bonding areas are formed to cover the bonding areas in the internal ends of the leads.

18. A lead frame according to claim 2, wherein channels and/or recesses are formed in the internal ends of the leads.

19. A lead frame according to claim 3, wherein channels and/or recesses are formed in the internal ends of the leads.

20. A lead frame according to claim 2, wherein projections are formed in the internal ends of the leads.

21. A lead frame according to claim 3, wherein projections are formed in the internal ends of the leads.

22. A lead frame according to claim 2, wherein through holes running through a thickness direction are formed in the internal ends of the leads.

23. A lead frame according to claim 3, wherein through holes running through a thickness direction are formed in the internal ends of the leads.

24. A lead frame according to claim 2, wherein hollows whose dimensions are larger than bonding areas are formed to cover the bonding areas in the internal ends of the leads

25. A lead frame according to claim 3, wherein hollows whose dimensions are larger than bonding areas are formed to cover the bonding areas in the internal ends of the leads

26. A lead frame according to claim 2, wherein hollows whose dimensions are larger than bonding areas are formed to cover the bonding areas in the internal ends of the leads, and wherein the internal ends of the leads including the bonding areas are expanded in prescribed directions.

27. A lead frame according to claim 2, wherein hollows whose dimensions are larger than bonding areas are formed to cover the bonding areas in the internal ends of the leads, and wherein the internal ends of the leads including the bonding areas are expanded in prescribed directions.

28. A semiconductor package according to claim 11, wherein channels and/or recesses are formed in the internal ends of the leads.

29. A semiconductor package according to claim 12, wherein channels and/or recesses are formed in the internal ends of the leads.

30. A semiconductor package according to claim 11, wherein projections are formed in the internal ends of the leads.

31. A semiconductor package according to claim 12, wherein projections are formed in the internal ends of the leads.

32. A semiconductor package according to claim 11, wherein through holes running through a thickness direction are formed in the internal ends of the leads.

33. A semiconductor package according to claim 12, wherein through holes running through a thickness direction are formed in the internal ends of the leads.

34. A semiconductor package according to claim 11, wherein hollows whose dimensions are larger than bonding areas are formed to cover the bonding areas in the internal ends of the leads

35. A semiconductor package according to claim 12, wherein hollows whose dimensions are larger than bonding areas are formed to cover the bonding areas in the internal ends of the leads
